(19) United States
(12) Patent Application Publication
(10) Pub. No.: US 2018/0259557 A1
(43) Pub. Date: Sep. 13, 2018

(54) MONITORING APPLIANCE STATUSES AND ESTIMATING ENERGY CONSUMPTION USING AN APPLIANCE STATUS SENSOR NETWORK

(71) Applicant: Ming Dong, Calgary (CA)

(72) Inventor: MING DONG, Calgary (CA)

(73) Assignee: MING DONG, Calgary (CA)

(21) Appl. No.: 15/950,170

(22) Filed: Apr. 11, 2018

(51) Int. Cl. G01R 21/133

(52) U.S. Cl. CPC G01R 21/133

(57) ABSTRACT

What are disclosed here are a technique and its embodiments to monitor the energy usage of any appliances in a house using two types of devices. One type of device is portable and senses appliance status change. Each can be connected to a certain appliance user decides to track. The other device monitors the total power consumption of the entire house. Once the appliance's status changes, such as being turned on, the device will send a signal along with the appliance's ID to the house power monitor. The house power monitor is then triggered to record the time stamp of this appliance's event and stores it in a database along with total house consumption data. With respect to total house power consumption and received event signals, energy consumptions of individual appliances can be calculated. Results can be sent to Internet/Ethernet or a display device and used for decision making.

### FIELD OF THE INVENTION

This invention relates to a method and system for monitoring home appliance statues and estimating energy consumption of home appliances according to the monitored statuses.

### BACKGROUND OF THE INVENTION

The electricity meter installed at the service entrance point of a utility customer can only record the energy consumption of the entire household. It cannot tell which appliances in the household consume the most energy or are least efficient. Market research has shown that the most valuable information to a household is the energy consumption data of various appliances. Such information is essential for a household to make sound energy saving decisions. The need to monitor the energy consumptions of appliances has been well recognized by industry. The simplest method is to connect a power transducer to each appliance of interest which can measure both current and voltage and to communicate the recorded data to a central data concentrator or display device. The power transducer works as an intermediate device which connects both appliance and electricity outlet. This is the direction pursued by U.S. Pat. Nos. 5,315,236, 4,207,557, 6,934,862, 6,950,725, 6,552,525 and U.S. patent application publication Ser. No. 11/276,337. While such a power sensor network based system can provide accurate measurement of appliances' energy consumption, it can be very inconvenient to enable such kind of connection for many bulky appliances such as refrigerator, oven, dishwasher, wash and dryer which actually take up a large portion of home energy consumption. Furthermore, for some appliances with hidden wires inside walls or ceilings such as lamps, the connection becomes infeasible.

On the other hand, sensors which can sense status of objects through acceleration, light and so on have been well developed. Examples are U.S. Pat. No. 7,907,838 B2, 2007/0214887 and US20070215794. However, none of those above are designed to serve home appliance status sensing purpose. The only related U.S. patent 20110054845 uses sound signal for diagnosis of home appliances. In terms of appliance energy monitoring, there is no available patent using above said sensors.

The invention presents a novel status sensor network. Instead of directly measuring current and voltage of appliances, the disclosed status sensor only measures the status change of appliances and it also has multiple sensory functions which can support convenient accesses to different types of appliances. All of those individual appliance status sensors communicate with a central total house consumption monitor. This way, status monitoring and energy estimation of home appliances can be achieved. The invention further includes a novel scheme to assist customers to understand their electricity consumptions through Internet/Ethernet.

### SUMMARY OF THE INVENTION

What are disclosed here are a technique and its embodiments to monitor the energy usage of any appliances in a house using two types of devices. One type of device is portable and senses appliance status change, called appliance status sensor. Each can be connected to a certain appliance user decides to track. The other device monitors the total power consumption of the entire house, called house power monitor. This invention works as follows: the appliance status sensor is applied to an appliance of interest. It can detect the status change of an appliance using plurality of sensors that are able to sense current, vibration, temperature, and light etc. Once the appliance's status changes, such as being turned on, the device will send an “event” signal along with the appliance's ID to the house power monitor. The house power monitor is then triggered to record the time stamp of this appliance's event and stores it in a database along with total house consumption data. Eventually, with respect to total house power consumption and received event information, energy consumptions of individual appliances can be calculated. The house power monitor also has the capability to send data to Internet/Ethernet or a display device.

The disclosed also includes two algorithms which are used by appliance status sensor and house power monitor. One algorithm is programmed into appliance status sensor, used to detect status change of individual appliance. The other algorithm is programmed into house power monitor and used to estimate energy consumption of individual appliances.

Further disclosed here is a platform of scenario simulation to assist customers to evaluate their electricity consumptions based on the appliance consumption data.

### BRIEF DESCRIPTION OF THE DRAWINGS

A clear understanding of the key features of the invention summarized above may be had by reference to the appended drawings, which illustrate the method and system of the invention, although it will be understood that such drawings depict preferred embodiments of the invention and, therefore, are not to be considered as limiting its scope with regard to other embodiments which the invention is capable of contemplating. Accordingly:

FIG. 1 is an illustration of the method and system of this invention showing an overall preferred embodiment of appliance monitoring system.

FIG. 2 is an illustration of the method and system of this invention showing different ways of connecting appliance status sensors with appliances.

FIG. 3 is an illustration of the method and system of this invention showing the functional diagram of automatic appliance sensor.

FIG. 4 is a flowchart of status change detection algorithm.

FIG. 5 is showing an example of status change detection using vibration sensing for an appliance

FIG. 6 is an illustration of the method and system of this invention showing the functional diagram of house monitor.

FIG. 7 is a flowchart of energy estimation algorithm.

FIG. 8 is showing an example of energy estimation using the invented method and system.

FIG. 9 is an illustration of the method and system of this invention showing the overall platform for scenario simulation.

### DETAILED DESCRIPTION OF THE INVENTION

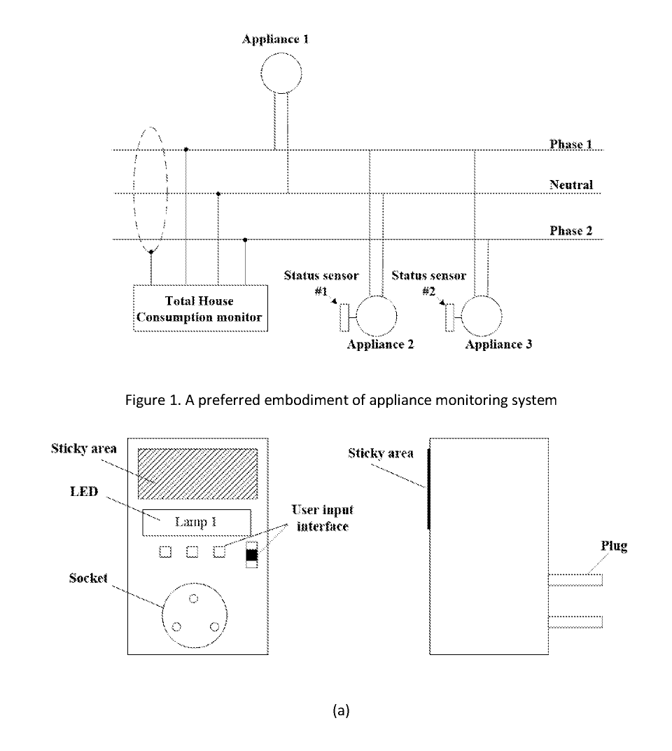

A preferred embodiment of the disclosed is shown in FIG. 1. In this figure, two hot electric wires are brought in home from utility. Depending on appliance's location and voltage demand (120V or 240V), various appliances is connected to either one of them or both. The house power monitor is located at the service entrance point of the house and is able to measure the current and/or voltage entering the house. The appliance status sensor is a portable multisensory device which can be attached or connected to any appliance and is able to sense the status change of the corresponding appliance. The system works in three steps:

1) Appliance status sensor: The user first enters the name or ID of the appliance to be tracked into the sensor. He/she then attaches or connects the sensor to the corresponding appliance. During this period, the appliance sensor keeps sensing the status of appliance automatically through one or more of its internal sensor chips. These sensor chips include but are not limited to temperature, light, vibration and current sensory chips. Once the appliance changes its operating mode, the sensor will send the house power monitor a triggering signal along with the appliance ID through wireless means.
2) House power monitor: The house power monitor includes three basic functions. Firstly, the monitor senses current/voltage values of the two hot phases at house entry point in nearly real time. The demand of sampling frequency is to adapt the accuracy required by energy estimation. In the meanwhile, the current/voltage data is stored in its memory and prepared to be reloaded afterwards. Secondly, the monitor keeps receiving triggering signals from appliance status sensors which have been connected to different appliances. Once a triggering signal is received, corresponding time stamp along with the appliance ID is stored. As time goes by, gradually, an event table that documents the status changes of various appliances of interest can be established. Thirdly, after time stamps are collected for a certain period, say half an hour, the house power monitor is switched to the energy estimation mode. Under this mode, the house power monitor reads the time stamps from event table for this given period. After that, with respect to the collected time stamps, it captures corresponding electrical changes of current and voltage. Finally, based on those changes, power information can be extracted and accordingly energy consumptions of various appliances during the given periods can be estimated.
3) Data analysis and display: The house power monitor may be connected to different display/analysis devices such as (a) a local display device, (b) the user's computer or (c) internet. These devices have data analysis capabilities to reveal additional useful information to the user. The appliance status sensor also has a display feature that displays simple information about the appliance being sensed.

It is clear that the disclosed can be extended to commercial and industrial facilities.

### A. Appliance Status Sensor

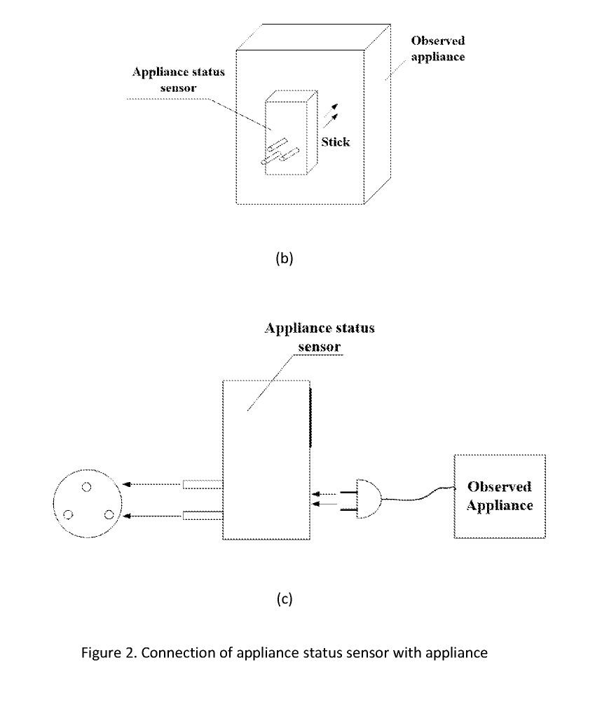

An appliance status sensor includes multi-sensory chips inside. This sensor can be either stuck onto the shell of an appliance or connected to the appliance electrically. The sticking way (FIG. 2-b) is very convenient, especially when it is difficult to make a connection electrically such as to a lamp with hidden wires in the ceiling or to a bulky oven. For the second way (FIG. 2-c), customers should view it as an electric socket so that the socket should be plugged into an outlet first and then the appliance can be plugged to the socket.

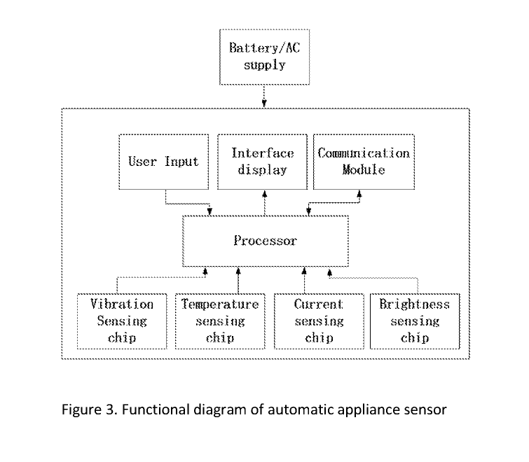

FIG. 3 shows the functional diagram of this appliance status sensor. It comprises at least four kinds of sensors: temperature sensor, brightness sensor, vibration sensor and current sensor. Those sensors can detect statuses of most appliances such as oven (temperature or current), lamp (brightness), laundry machine (vibration or current). It should be noticed that the current sensing method will always work if an appliance can be plugged into the sensors. This sensing method can also record the standby power consumption of an appliance. The user can use its input buttons/switches to select which sensing method is wanted. The user is also requested to enter an ID for the appliance monitored. For example, the ID can be in the form of “Refrigerator 1”, “Lamp 2” etc.

An example process is as follows: the user first enters an ID. As an option, the user can also select the sensing method which will be applied to the appliance. He/she then applies the device to the appliance (attach it, plug into it etc.) when the appliance is off. The sensor will start to detect the change of the statuses of the appliance. If there is a change, it will call its wireless module to inform house power monitor immediately. The sensor also sends the appliance's ID code to the house power monitor so that the received signals can be linked to the specific appliance.

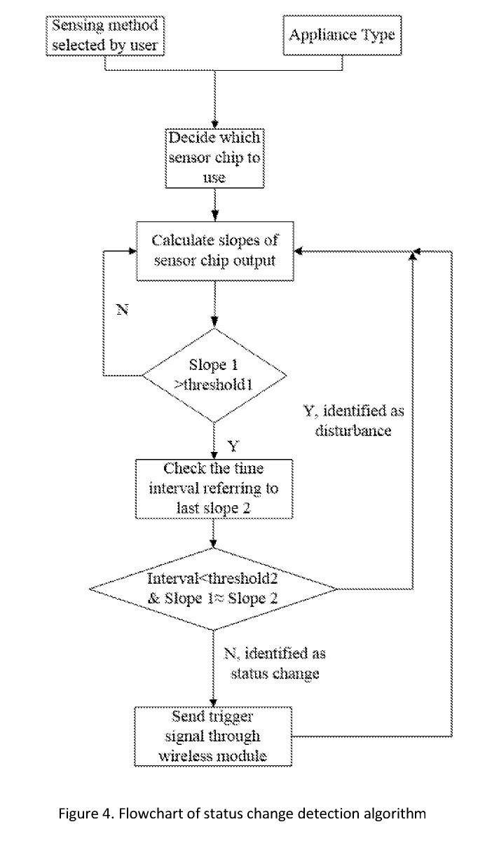

To detect status change of appliance, specific algorithm is also embraced in this disclosed. Its flowchart is illustrated in FIG. 4. Although there are multiple sensory chips inside appliance status sensor, only one of them will be selected for monitoring of specific appliance. Which one to be activated is determined ether through user's manual selection or through default settings that are pre-defined according to appliance type in advance. For instance, based on common sense, lamp is likely to be effectively sensed through brightness sensing chip while a fridge with a running motor inside is likely to be sensed through vibration sensing chip.

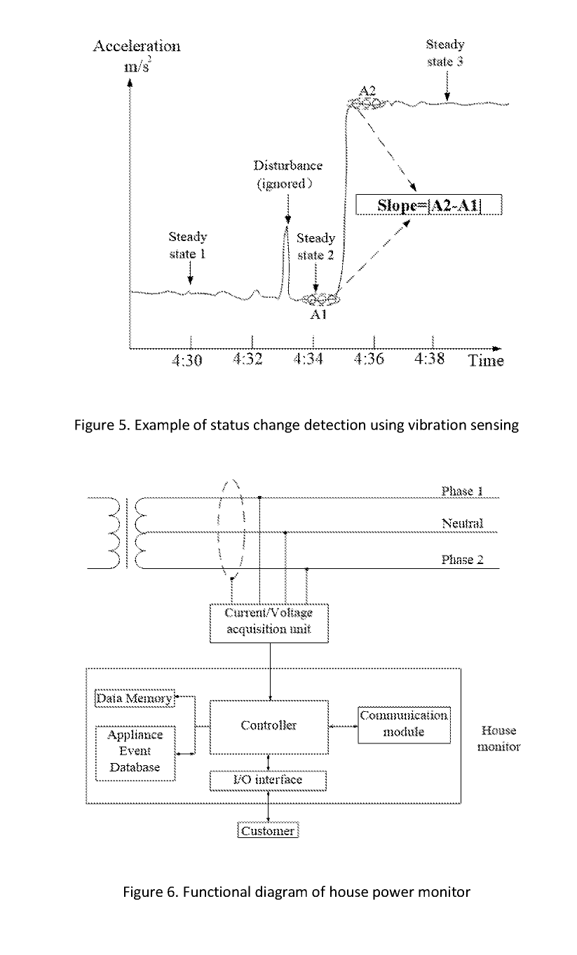

After sensory chip to be observed is ascertained, changes of its output values will be constantly monitored as shown in FIG. 5. A variable named as slope is dynamically calculated as the differential between the average of the last three data points and the average of neighboring three points before. Usually, a status change on the operation of an appliance can be observed as either a rising or falling step on its output curve. And accordingly, a relatively large slope value will be observed in comparison to a much smaller value due to natural fluctuation of output. Thus, the instant slope value is compared to a threshold, say 20% of previous steady state value, to determine whether it remains in steady state. There is an exception which is necessary to be concerned: disturbance can also result large slope value. One example is vibration caused by occasional human activities nearby. Nevertheless, a common characteristic is that a disturbance usually occurs in the form of a short pair of large step changes (spike) as shown in FIG. 5. To put it another way, two almost equally valued slopes can be observed within a limited time interval when a disturbance occurs. To cope with this conflict, an additional restriction is also considered in flowchart of FIG. 4. Eventually, only when a large slope is determined as a real status change caused by corresponding operation change of appliance, a triggering signal will be sent to the house power monitor through the wireless module of appliance status sensor. After this is done, program is set back to the beginning of the loop and continues monitor the slopes as time progresses.

Besides, the appliance status sensor also contains a display function on its interface which displays simple energy information about the appliance being sensed after the house power monitor estimates the energy of appliance and send it back to status sensor. In this case, the appliance status sensor also works as a portable display device for the convenience of customers to check.

It should be noted, in the preferred embodiment, appliance sensor has two sets of power supplies. AC supply is enabled when appliance sensor is plugged into an outlet using its current sensory function. However, for the other sensory functions when no AC power is connected in, battery has to be used.

### B. House Power Monitor

The house power monitor is installed at customer-utility interface point. It is able to measure the currents flowing to the household and preferably the voltages supplied to the household as well. If only current information is available the power consumption results are approximate. But the energy consumption of an appliance relative to the energy consumption of the entire house is as accurate as to the case where the voltage information is available. Possible embodiments of the house power monitor are (a) utility power meter which has the capability to record current and voltage waveforms, (b) a dedicated power monitor installed by the customer and (c) a piece of hardware that can be integrated into the utility power meter.

In either case, the house power monitor may consists of all or some of the following: current/voltage acquisition and processing unit, data memory, computational (controller) unit, communication module and the I/O interface to internet/Ethernet. The house power monitor has four operating modes: measurement mode, event recording mode, energy estimation mode, and reading mode. House power monitor can automatically switch among these modes.

In the measurement mode, house power monitor constantly samples currents of two hot phases and voltages between the two phases and neutral. Preferably, the monitor has high sampling rate such as 128 samples per electric cycle for current and voltage recording. In the meanwhile, active power can be calculated at a preferred one-second basis and the power values labeled with time are stored in the data memory unit of house power monitor.

Once the communication module receives a triggering signal from a certain appliance status sensor, measurement mode will be temporarily interrupted for a short period and switched to event recoding mode. In this mode, time stamp at the instant of triggering signal being received will be recorded, along with the appliance's ID information. The record will be documented in the appliance event database that has the capability to store a recent period, say, 2 hours' events of all appliances being tracked. The database is further used for energy estimation purpose.

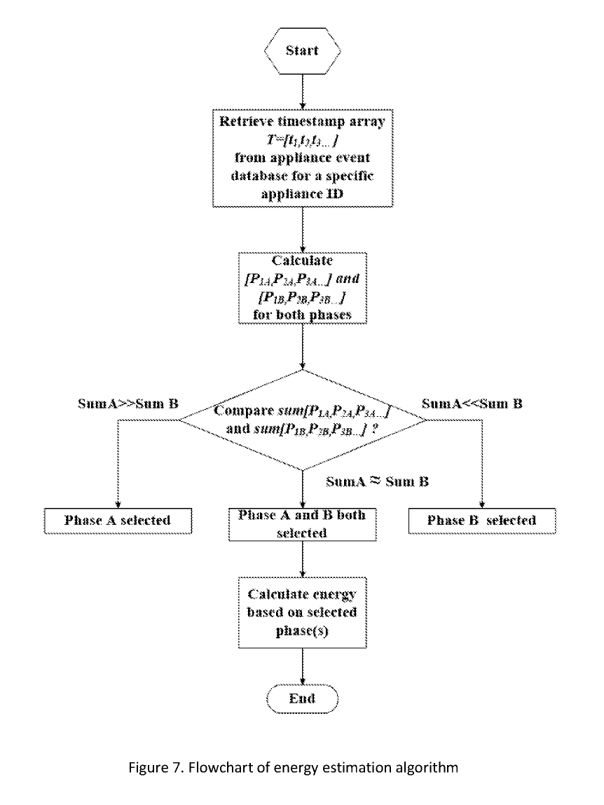

Once in a while, energy estimation mode will be wakened and calculate the energy consumed by specific appliances. This mode can run in background so that it will not disturb normal measurement and event recoding. The flowchart of energy estimation algorithm is shown in FIG. 7.

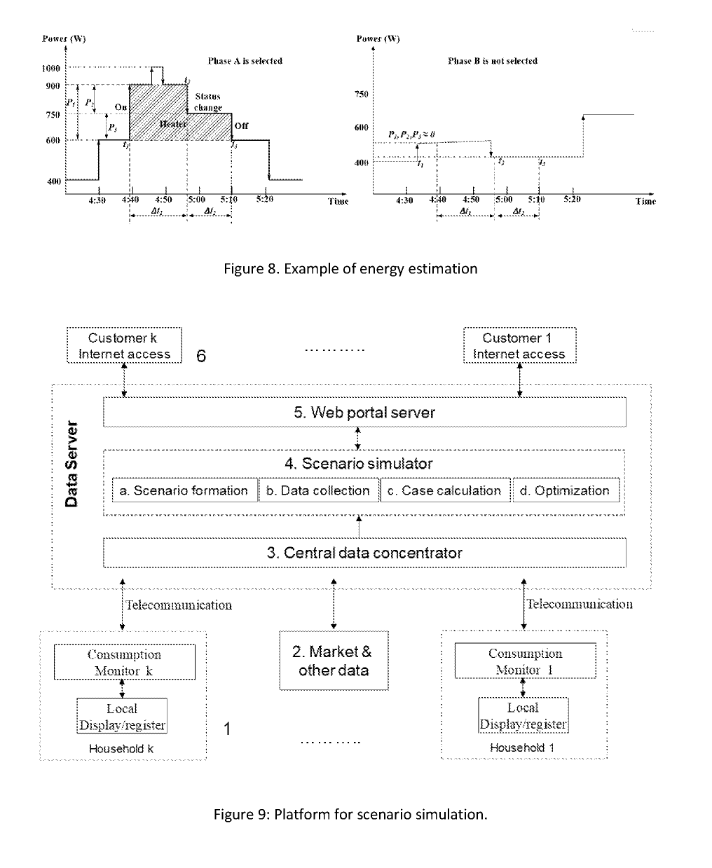

As can be seen, in the beginning, timestamp array T=[t1,t2,t3 . . . ] is retrieved with respect to appliance ID from appliance event database that stores recent events of all interested appliances. After that, power changes at instants indicated by timestamp array at both phases are calculated. Preferably, one can calculate the differential between average power values of 3 seconds before the instant t and after it. However, it should be noted that since there are two hot phases in most North American residential households but one specific appliance may be connected to one or them, a step to judge phase connection for given appliance is necessary. One efficient way to judge is to compare the summation of power changes of given instants at both phases. If summation at phase A is much larger than the one at phase B, the appliance is determined to be connected to phase A; similarly, if phase B is much larger, the appliance is determined to be connected to phase B; however, if the two summations are roughly the same, it indicates the appliance is connected between phase A and phase B. Once the power changes and phase connection are made clear, energy can be calculated applying the following formula:

$$E = {\sum }_{i = 1}^{k - 1} {P}_{i} Δ {t}_{i}$$

Where P_i is the power change of selected phase at timestamp t_i; Δt_i is the time interval between t_i and t_(i+1); k is the total number of recorded timestamps in the given period. An illustration of above energy estimation process on a heater's operation is provided in FIG. 8.

In reading mode, the monitor transmits the energy consumption results to the display/analysis unit. The unit can be a dedicated local display device, the appliance status sensor which also works as a display device or user's computer (through internet or Ethernet). The display device may also receive other information such as real-time power price and electricity rate schemes from other sources.

### C. Data Analysis and Display

The appliance energy consumption results obtained by the house power monitor can be used in a number of ways. Some of the examples are
Energy cost of an appliance over one working cycle, one week or one month
Average energy cost of an appliance per each use
How often an appliance is activated and the average duration of each operation
Comparison of the energy costs for sensed appliances in a household
Identification of abnormal energy consumption patterns of an appliance

Appliance data are also very useful to utilities. For example, a utility can know, at any given time, how many residential refrigerators are operating and what is their collective power demand level. Since refrigerators can be shut down for a short period without causing inconvenience to the owners, the data presents the potential amount of loads that can be shed by the utility if power system emergency happens. Another two uses of the data are for a utility (a) to confirm if a demand response program is indeed implemented by subscribed customers and (b) to measure the effectiveness of certain energy conservation programs. On the customer service site, the host utility can provide customers power bills that contain a list of energy costs for various appliances.

There are advanced ways to utilize the data if an internet server is used. For example, the energy consumption level of an appliance can be compared with similar ones in other households. A novel application of the appliance data, scenario simulation, is also disclosed here.

Scenario simulation can be defined as follows: a user simulates different operation schedules of various appliances, different electricity rate structures and other different scenarios to determine the resulting impact on his/her electricity bill.

In one embodiment, one can create multiple scenarios of appliance usage schedules or patterns. One of the scenarios is, of course, the pattern actually practiced by the user. Since the electricity price may be different for different time of a day, the resulting electricity cost to the user will be different for different scenarios. The results can be displayed to users. Such simulations can only be done when the appliance energy consumption data is available. The simulation is often run for a period of one week or one month to determine if meaningful savings exist. An optimization algorithm may be used to find the most cost-effective schedule of appliance operations. In yet another application, the user may simulate the use of a new appliance to determine if replacing an old appliance will pay off by savings in power bill.

The user may also use scenario simulation to evaluate different electricity retailers. Each city often has multiple electricity retailers with different rate structures. At present, it is impossible to determine which retailer charges least power bill for a user. In this embodiment, the retailing rates in the user's area are first obtained and stored in a database. The energy consumption patterns over the past several months are also stored. The various retailing rates are then applied to the energy consumption patterns to determine the resulting cost if the user had switched to a different retailer.

Due to the involvements of a lot of data and the complex nature of user interface, the preferred embodiment of scenario simulations is a centralized data server with internet as its front end. The flow chart of scenario simulation is shown in FIG. 9.

In the figure, item 1 represents the disclosed appliance monitoring system for a particular household. Item 2 represents the data collected from other sources. Examples are the billing rate and schedule of electricity, weather condition, energy consumption characteristics of new appliances as submitted by manufacturers, and promotional programs of utilities etc. Item 3 collects and organize the various data in a database. Item 4 represents the computational engine for scenario simulation which consists at least four components, a) scenario formation, b) data collection, c) case calculation and d) optimization of scenarios. Item 5 is the server for internet. This server interfaces the disclosed system with the customer. The customer enters scenario information and other data into the system through internet.

What is to be claimed are:

1. A status monitoring device which can sense status change of home appliances.

2. An energy monitoring system consisting of appliance status monitoring devices and a house power monitor.
